(19) United States
(12) Patent Application Publication
(10) Pub. No.: US 2022/0358386 A1
(43) Pub. Date: Nov. 10, 2022

(54) Learning method for the determination of a level of a space-time trending physical quantity in the presence of physical obstacles in a chosen spacial zone

(71) Applicant: COMMISSARIAT A L’ENERGIE ATOMIQUE ET AUX ENERGIES ALTERNATIVES, PARIS (FR)

(72) Inventors: Mouhcine MENDIL, GRENOBLE (FR); Sylvain LEIRENS, GRENOBLE (FR); Patrick ARMAND, ARPAJON (FR); Christophe DUCHENNE, ARPAJON (FR)

(21) Appl. No.: 17/715,997

(22) Filed: Apr. 8, 2022

(30) Foreign Application Priority Data
Apr. 27, 2021 (FR) 2104371

(51) Int. Cl. G06N 7/00; G06N 20/00

(52) U.S. Cl. CPC G06N 7/00; G06N 20/00

(57) ABSTRACT

A method, implemented by computer, for determining a level of a space-time trending physical quantity in the presence of physical obstacles in any zone, includes in a learning phase, determination, by means of machine learning receiving as input a first set of physical obstacles and a first set of data, of a model for the physical quantity in the predefined zone; in an operation phase, determination of a second level of the physical quantity in any zone, from the model for the physical quantity receiving as input a second set of physical obstacles, distinct from the first set of physical obstacles, and a second set of data.

The invention relates to the field of the modelling of physical phenomena. It relates to a learning method for the determination of a level of a space-time-trending physical quantity in the presence of physical obstacles in a chosen spatial zone.

The understanding of various phenomena in the real world is these days largely based on partial differential equations (PDEs). It is in fact thanks to the modelling of these phenomena through PDEs that it is possible to understand and assess the role of the parameters involved, and obtain predictions, sometimes extremely accurate predictions.

PDEs are used in many fields of physics, notably in acoustics, in fluid mechanics, in electrodynamics and in quantum mechanics.

The focus here is the PDEs involving multivariate functions u:Ω→ [symbol] ⁿ and their partial derivatives, defined in a space Ω∈ [symbol] ^{m}. The general form of the PDE is as follows:

F(x,uₓ,uₓₓ, . . . )=0,x∈Ω (1)

in which F is an a priori nonlinear function and

$${u}_{\underbrace{x…x}_{\times k}}$$

represents the kth order partial derivatives vector.

To better illustrate the notation, consider x=(x₁, x₂, . . . , xₘ)∈Ω and u=(u₁, u₂, . . . , uₙ)∈ [symbol] ^{nΩ}. The following apply:

$$\{ \begin{matrix}{u}_{x} = ( {u}_{{x}_{1}} , {u}_{{x}_{2}} , … , {u}_{{x}_{m}} ) \\ {u}_{xx} = ( {u}_{{x}_{1} {x}_{1}} , {u}_{{x}_{1} {x}_{2}} , … , {u}_{{x}_{1} {x}_{m}} , {u}_{{x}_{2} {x}_{1}} , … , {u}_{{x}_{m} {x}_{m}} )\end{matrix}$$

$$\{ \begin{matrix}{u}_{{x}_{i}} = ( \frac{\partial {u}_{1}}{\partial {x}_{i}} , \frac{\partial {u}_{2}}{\partial {x}_{i}} , … , \frac{\partial {u}_{n}}{\partial {x}_{i}} ) , i ∈ \{ 1 , 2 , … , m \} \\ {u}_{{x}_{i} {x}_{j}} = ( \frac{{\partial }^{2} {u}_{1}}{\partial {x}_{i} \partial {x}_{j}} , \frac{{\partial }^{2} {u}_{2}}{\partial {x}_{i} \partial {x}_{j}} , … , \frac{{\partial }^{2} {u}_{n}}{\partial {x}_{i} \partial {x}_{j}} ) , ( i , j ) ∈ {\{ 1 , 2 , … , m \}}^{2}\end{matrix}$$

To the equation (1) are added a set of constraints of physics (for example conservation of mass and energy balance) and spatial constraints linked to the medium in which the phenomenon is trending. It should be noted that these constraints are correlated. These constraints can be written as below:

C_{eq}(x,uₓ,uₓₓ, . . . )=0,x∈Ω (2)

C_{ineq}(x,uₓ,uₓₓ, . . . )≤0,x∈Ω (3)
with C_{eq} and C_{ineq} a priori nonlinear functions.

The PDE solution consists in finding the function u* (assumed to exist and to be unique) which satisfies (1) and observes the constraints (2) and (3).

In their mathematical formulation, the PDEs jointly represent the spatial and temporal variations of the phenomenon, that is to say the physical quantity, being studied. In simple and known cases, they can be resolved analytically. However, generally, it is rare to be able to determine the exact solutions. The existence of powerful computers does nevertheless make it possible these days to obtain, through numerical methods, approximate solutions even for very complex PDEs.

In particular, a few PDEs keep their complexity from their nonlinearity (for example the Navier-Stokes equation). For others, the complexity stems from the spatial constraints interfering with the phenomenon concerned (nonuniform medium, marked by the presence of physical obstacles such as a wall, a vehicle, a post, a building), which make the problem difficult to formulate (need to discretize) and to solve. In these two cases, the implementation of numerical solving methods requires significant computation and memory resources.

Faced with this limitation, solutions oriented towards machine learning for solving PDEs have recently emerged.

Depending on the complexity of the approaches used, the learning phase can be lengthy and data-intensive. That said, the learning is performed just once and the use of the model produced is effective and economical in terms of resources.

Specifically, there are two approaches for solving PDEs using learning methods.

The first approach addresses symbolic solving with discovery of the PDE. It relies on a sequence of two separately trained learning models.

First of all, a dense neural network proceeds to formulate the PDE including the spatial constraints, from a set of observations as described in the document PCT/US2017/035781. This entails explicitly determining the coefficients of the function F (equation 1) from the observed dynamics and finding the simplest possible (finite and exact) mathematical expression combining F, C_{eq} and C_{ineq} in a same system of equations.

Next, from the analytical form of the PDE found in the preceding step, a transformer (LSTM-type architecture) constructs a computation tree and symbolically solves the system of equations, as is described in the reference [4]. The result thereof is an exact (continuous) expression of the solution of the PDE.

The second approach consists in training a regression model with 2D or 3D observations representing the space-time trending of the phenomenon. The method is based on historical realizations to infer underlying nonlinear dynamics. Once the learning converges, the model makes it possible to make predictions given an initial state. Several architectures are used, as described in the references [2] and [3], most relying on recurrent networks for capturing the time-dependency.

The two approaches mentioned above can model with great accuracy several PDE families. However, the models produced are valid only for the spatial constraints on which they were trained. That means that a new learning must be performed on each change in the environment (or for a new environment) of the phenomenon being studied. The idea of constructing a library of models by combining constraints can rapidly be abandoned because of the unrealistic quantity of data and storage space that that would require.

In the solutions of the prior art, the reuse of the models in other environments is curbed by the absence of an effective representation of the spatial constraints during the learning.

The invention aims to overcome all or part of the problems cited above by proposing a learning method for solving partial differential equations of physical phenomena subject to spatial constraints. The proposed method makes it possible, at the end of the learning, to approximate the solution of the PDE for initial conditions and under spatial constraints similar to or different from those encountered in the learning phase. The initial conditions form part of the learning input data for the learning phase.

The subject of the invention is a method, implemented by computer, for determining a level of a space-time-trending physical quantity in the presence of physical obstacles in a chosen spatial zone, the trending of said physical quantity being governed by a system of partial differential equations, the method comprising the following steps:
in a learning phase, determination, by means of machine learning receiving as input a first set of physical obstacles belonging to a first learning spatial zone and a first set of initial conditions, of a model for said physical quantity, and, optionally, of a first level of the physical quantity in the learning spatial zone;
in an operation phase, determination of a second level of the physical quantity in a second spatial zone chosen from the model for said physical quantity receiving as input a second set of physical obstacles, distinct from the first set of physical obstacles, and a second set of initial conditions,
i. display of the second level of the physical quantity determined in the chosen spatial zone by means of a graphical interface,
ii. determination of applicable protection measures if the second level of the physical quantity reaches a previously defined alert threshold.

Advantageously, the step of determination of the model for said physical quantity comprises the steps of:
determination of a simplified solution of the system of partial differential equations in the absence of physical obstacles;
representation of the first set of physical obstacles in the learning spatial zone in the form of a first matrix of spatial constraints;
application, to the simplified solution, of a masking function parameterized by the first matrix of spatial constraints to obtain a first intermediate solution of the system of partial differential equations in the presence of the first set of physical obstacles;
application, to the first intermediate solution, of a correction function determined by a neural network, to obtain the model for said physical quantity and a first corrected solution of the physical quantity in the learning spatial zone;
application, to the first corrected solution, of the masking function parameterized by the first matrix of spatial constraints to obtain the first level of the physical quantity of the system of partial differential equations in the learning spatial zone in the presence of the first set of physical obstacles.

Advantageously, the step of determination of the second level of the physical quantity in a chosen spatial zone comprises the following steps:
representation of the second set of physical obstacles in the chosen spatial zone in the form of a second matrix of spatial constraints;
application, to the model, of a masking function parameterized by the second matrix of spatial constraints to obtain a second intermediate solution of the system of partial differential equations in the presence of the second set of physical obstacles;
application, to the second intermediate solution, of the correction function of the model, to obtain a second corrected solution of the physical quantity in the chosen spatial zone for the second set of physical obstacles;
application, to the second corrected solution, of the masking function parameterized by the second matrix of spatial constraints to obtain the second level of the physical quantity of the system of partial differential equations in the chosen spatial zone in the presence of the second set of physical obstacles.

Advantageously, the masking function is a group of convolution operations with nonlinear activation function.

Advantageously, the correction function is determined in a learning phase comprising a step of execution of several iterations of a machine learning algorithm, receiving as input the intermediate solution, the machine learning algorithm being configured to determine the correction function.

Advantageously, the iterations of the machine learning algorithm are stopped after the execution of a predetermined number of iterations, or when the error between the level of the physical quantity in the learning spatial zone and a reference level of the physical quantity in the learning spatial zone is lower than a predetermined convergence threshold.

In one embodiment of the method according to the invention, the physical quantity is a pollutant, preferentially chemical or sound.

In one embodiment of the method according to the invention, the machine learning of the model performed in the learning phase is fed by learning data comprising a mapping or morphology of the real learning spatial zone, comprising said first set of physical obstacles.

In one embodiment of the method according to the invention, the learning, the learning data further comprise different sets of initial conditions applied to the learning spatial zone comprising at least different sets of positions of the sources of emission of said physical quantity in the learning spatial zone.

In one embodiment of the method according to the invention, the different sets of initial conditions comprise different models of meteorological conditions impacting the learning spatial zone.

The invention relates also to a computer program comprising instructions for the execution of the method according to the invention, when the program is run by a processor.

The invention relates also to a processor-readable storage medium on which is stored a program comprising instructions for the execution of the method according to the invention, when the program is run by a processor.

Other features and advantages of the present invention will become more apparent on reading the following description in relation to the following attached drawings.

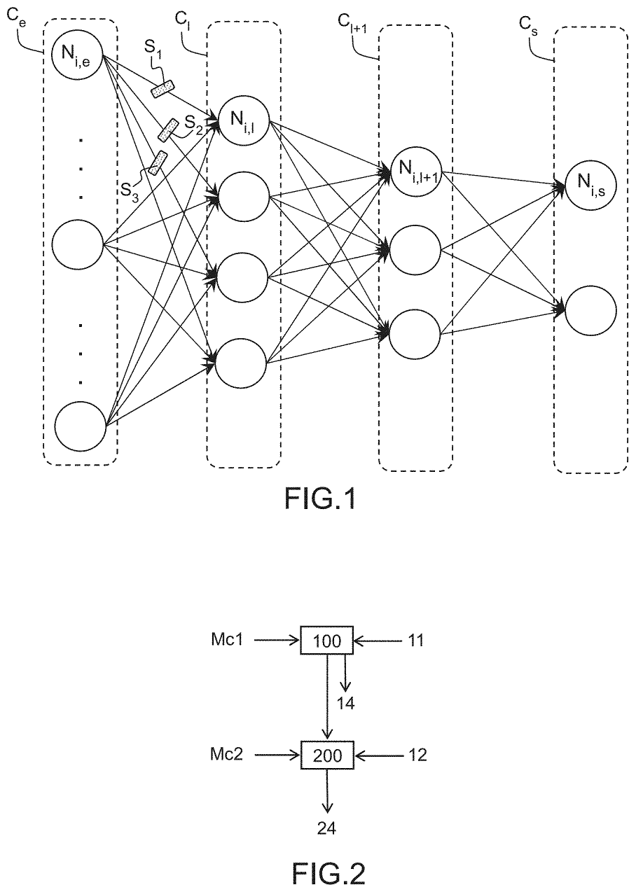

FIG. 1 represents, for explanatory purposes, a general scheme of an artificial neural network that can be used in the context of the invention;

FIG. 2 represents a general outline schematic of the method for determining a level of a space-time-trending physical quantity in the presence of physical obstacles in a chosen zone with a learning phase and an operation phase;

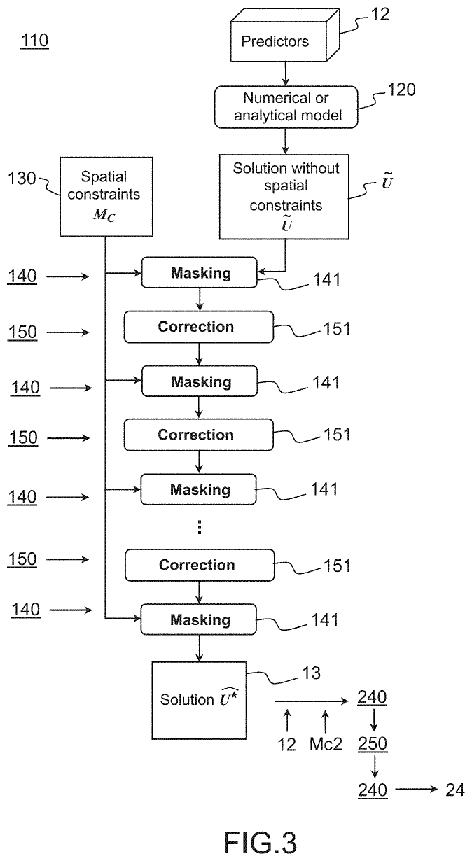

FIG. 3 represents a general outline schematic of the operation of a learning procedure for solving a PDE subject to spatial constraints according to an embodiment of the invention;

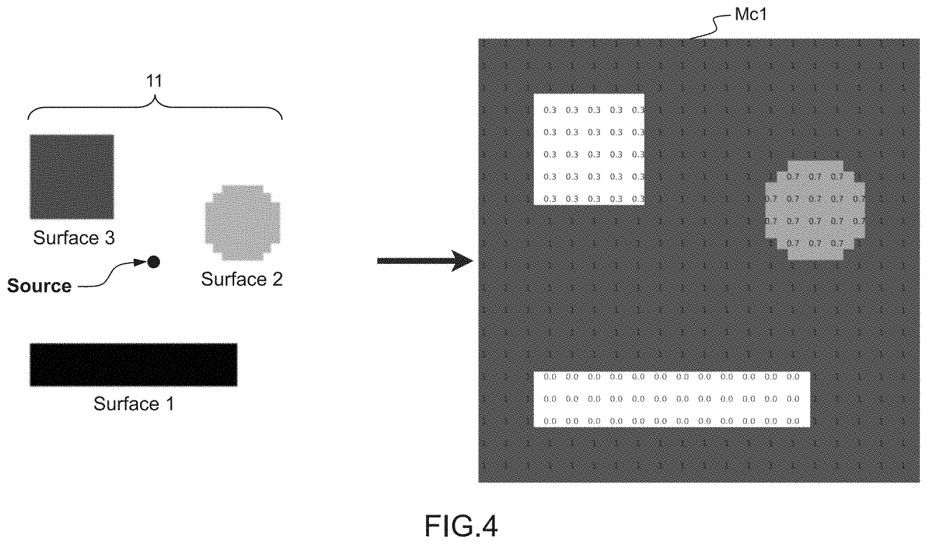

FIG. 4 schematically represents an illustration of a constraint matrix according to an embodiment of the invention;

FIG. 5 represents a general outline schematic of the masking function according to an embodiment of the invention;

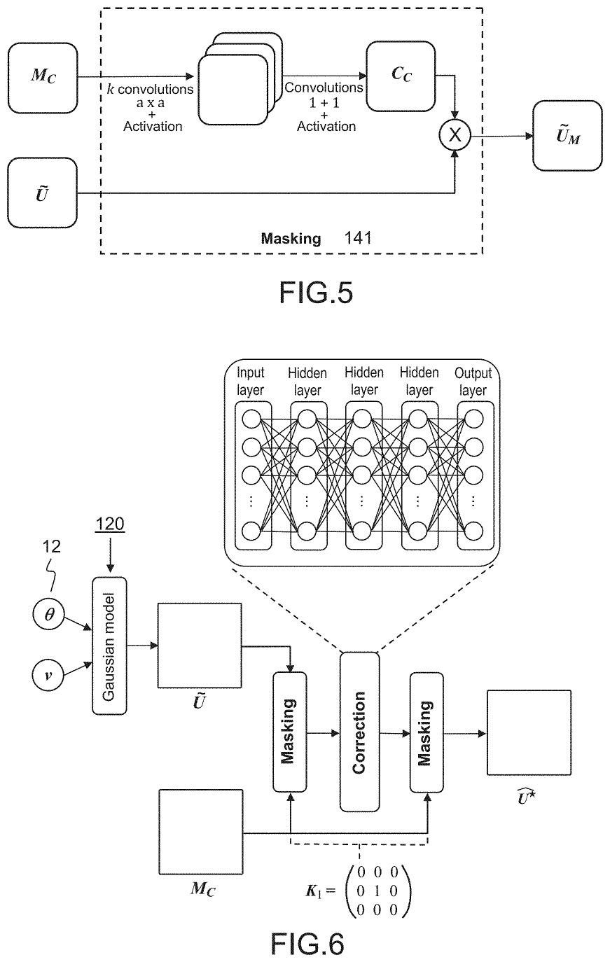

FIG. 6 represents a flow diagram detailing the steps of implementation of a learning procedure for solving a fluid mechanics PDE according to a first exemplary embodiment of the invention;

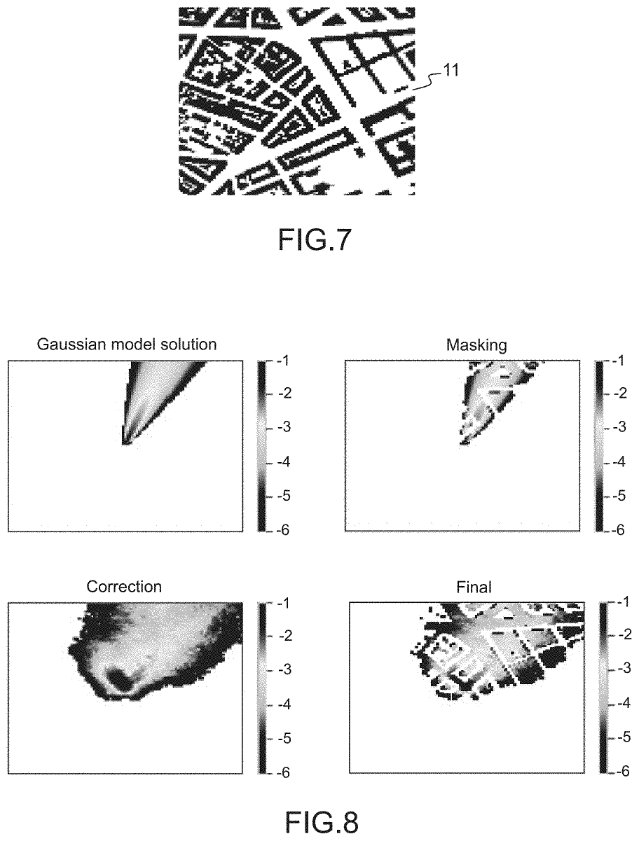

FIG. 7 schematically represents an illustration of physical obstacles (town centre of Grenoble) to be taken into account in a constraint matrix according to the first exemplary embodiment of the invention;

FIG. 8 illustrates maps of concentrations (logarithmic scale) of the final result and of the intermediate results of the learning model (in operation phase) on the atmospheric dispersion of a pollutant in the town centre of Grenoble according to the first exemplary embodiment of the invention;

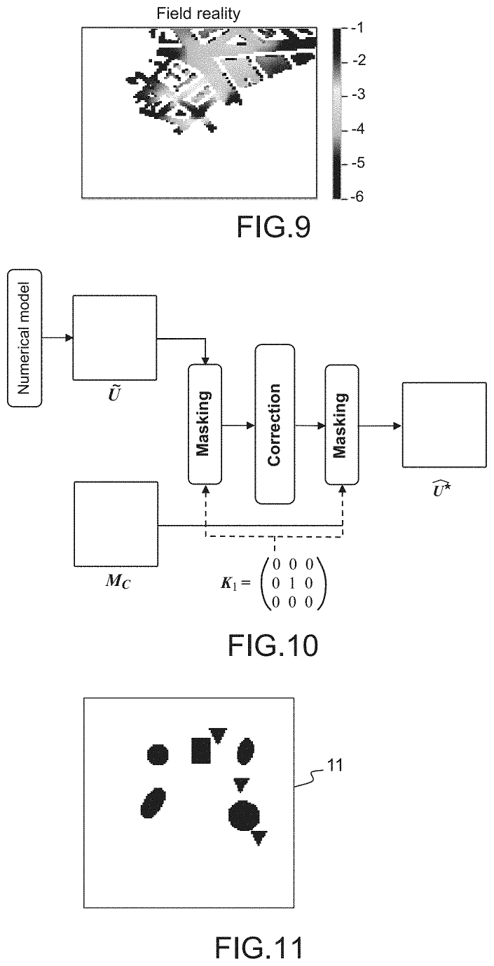

FIG. 9 represents the distribution of the pollutant simulated by a reference CFD model and likened to the terrain reality;

FIG. 10 represents a flow diagram detailing the steps of implementation of a learning procedure for solving an acoustic wave propagation PDE according to a second exemplary embodiment of the invention;

FIG. 11 schematically represents an illustration of physical obstacles to be taken into account in a constraint matrix according to the second exemplary embodiment of the invention;

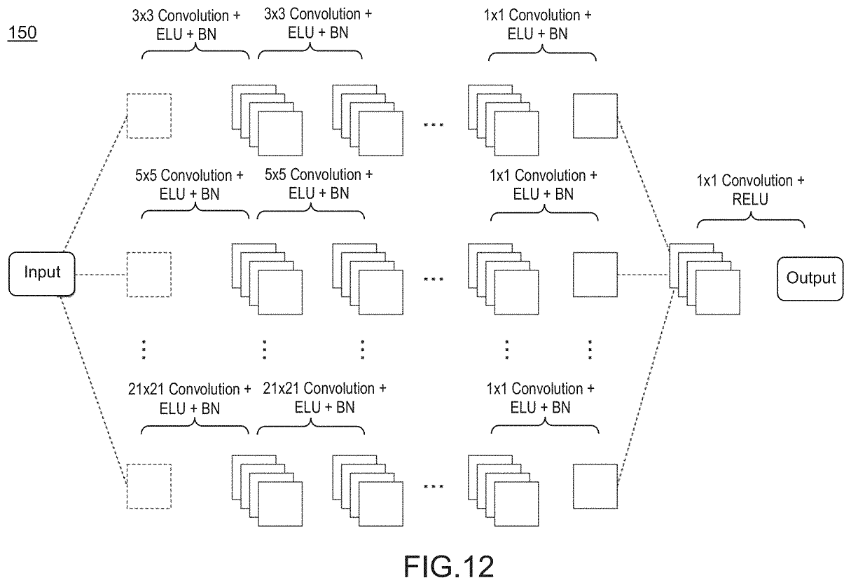

FIG. 12 represents a general outline schematic of the correction function for the acoustic propagation modelled by a multiscale convolution network according to an embodiment of the invention;

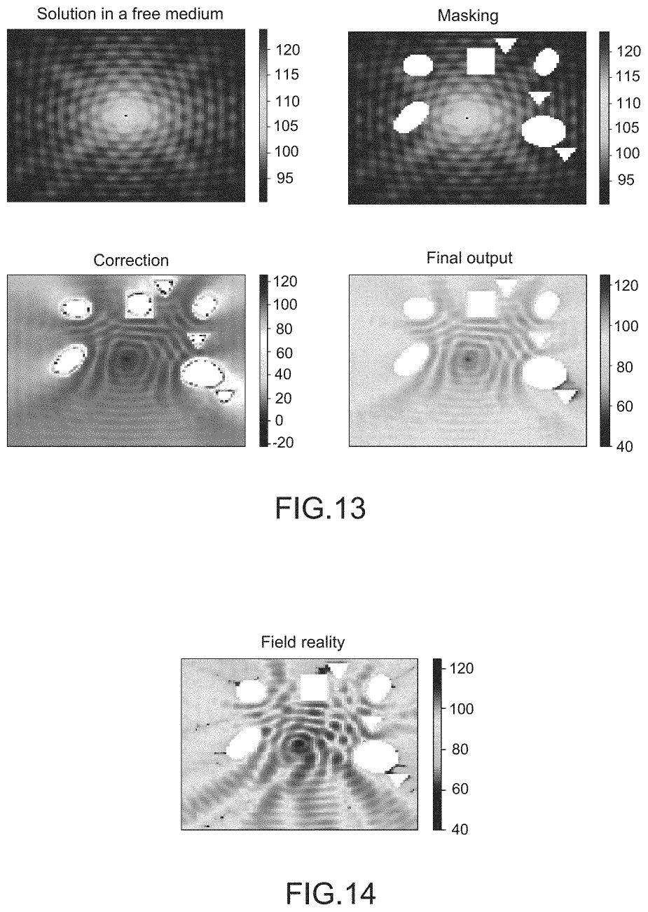

FIG. 13 illustrates maps of acoustic pressure levels (in decibels) of the final result and of the intermediate results of the learning model (in operation phase) on the acoustic propagation in a medium with obstacles according to the second exemplary embodiment of the invention;

FIG. 14 represents the acoustic pressure levels, simulated by the automata model described in the reference [5] and likened to the field reality;

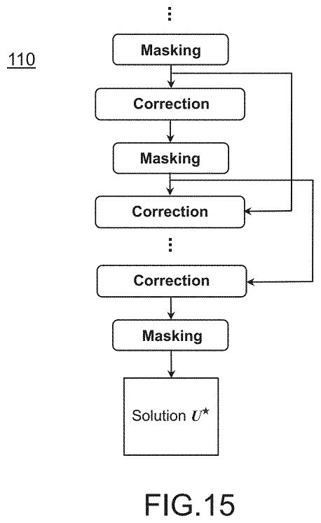

FIG. 15 represents an outline schematic of a variant of the learning procedure for solving a PDE subject to spatial constraints according to another embodiment of the invention.

FIG. 1 represents a general outline schematic of an artificial neural network, for example a convolutional neural network. A neural network is conventionally composed of several layers Ce, Cl, Cl+1, Cs of interconnected neurons. The network comprises at least one input layer Ce and one output layer Cs and at least one intermediate layer Cl, Cl+1. The neurons Ni,e of the input layer Ce each receive as input an input datum. The input data can be of different natures depending on the application targeted. In the context of the invention, the input data are matrices representing a physical quantity. The general function of a neural network is to learn how to solve a given problem which can notably, but not solely, be a problem of mathematical transformations or of classification. A neural network is, for example, used in the field of the modelling of the space-time dynamics of a phenomenon or in the field of the classification of images or of image recognition or, more generally, the recognition of features which can be of various natures (visual, sound or both at once). Each neuron of a layer is connected, by its input and/or its output, to all the neurons of the preceding or next layer. More generally, a neuron can be connected to only a part of the neurons of another layer, notably in the case of a convolutional network. The connections between two neurons Ni,e, Ni,I of two successive layers are made through artificial synapses S1, S2, S3 which can be produced, notably, by digital memories or by memresistive devices. Two operations follow one another within a neuron: 1) Calculation of the linear combination of the input values weighted by associated synaptic weights, to which is added a bias term. 2) Transformation of the result by a so-called activation nonlinear function (for example ReLU or sigmoid). The coefficients of the synapses and the biases can be optimized using a learning mechanism of the neural network. The objective of the learning mechanism is the training of the neural network to solve a defined problem. This mechanism comprises two distinct phases, a first phase of propagation of activations of the input layer to the output layer and a second phase of error gradient backpropagation from the output layer to the input layer with, for each layer, an updating of the weights of the synapses and of the biases. In the case of supervised learning, the cost function used during the learning calculates the error between the values estimated (during the forward-propagation) by the neural network and the results expected (assumed known). The aim, generally, is to minimize this error (by backpropagation) according to the problem to be solved.

The description of FIG. 1 is given by way of illustration of a neural network known to the person skilled in the art. Based on his or her knowledge, the person skilled in the art knows how a neural network operates and how to use it. The invention proposes determining a resolution model composed of a sequence of operations (called masking and correction), the parameters of which are determined by learning. On reading the description, the person skilled in the art will know how to implement the principles of the invention.

The invention is based on a particular use of different types of artificial neural networks to solve a problem of determination of a level of a physical quantity, governed by PDEs, with space-time trending in the presence of physical obstacles in a chosen spatial zone, for example an urban zone. The general principles introduced above provide an introduction to the basic concepts used to implement the invention.

FIG. 2 represents a general outline schematic of the method for determining a level of a space-time-trending physical quantity in the presence of physical obstacles in a chosen spatial zone with a learning phase and an operation phase. The trending of said physical quantity is governed by a system of partial differential equations. The method, implemented by computer, for determining a level of a space-time-trending physical quantity in the presence of physical obstacles in a chosen spatial zone comprises a learning phase 100 and an operation phase 200. In the learning phase 100, the first step is a step 110 of determination, by means of machine learning receiving as input a first set of physical obstacles 11 present in a predefined learning spatial zone and a first set of initial conditions 12, of a model 13 for said physical quantity, and, optionally, of a first level 14 of the physical quantity in the learning spatial zone.

The learning data used in the learning phase 100 are composed of a topography or mapping or morphology, in all cases three-dimensional, of a real spatial zone, for example an urban zone comprising a set of buildings. This zone constitutes a learning zone. The learning data also comprise a set of initial conditions or learning data which can be different positions of the sources of emission of the physical quantity in the learning zone and/or different meteorological conditions which impact the learning zone. Thus, the variability of the learning data is produced by varying the initial conditions 12 for a predefined learning zone comprising a set of physical obstacles 11.

In the operation phase 200, a second level 24 of the physical quantity in a zone chosen by the user is determined (step 210), from the model 13 for said physical quantity receiving as input a second set of physical obstacles 21 present in the chosen zone, distinct from the first set of physical obstacles 11, and a second set of initial conditions 22. The zone chosen in the operation phase is different from the predefined learning zone for the learning phase and thus comprises a second set of physical obstacles 21 different from the first set of physical obstacles 11. The method according to the invention makes it possible to determine the model for the specific physical quantity obtained with a learning phase with specific spatial constraints. Also, the method makes it possible to use this same model subsequently with another set of spatial constraints, hitherto unknown to the model. In other words, the model obtained for said physical quantity can be used with other spatial constraints (that is to say other physical obstacles), different from those used during the learning phase. As will emerge from the description and the examples below, owing to the flexibility and the capacity for generalization of the method of the invention, no additional relearning is necessary.

The trained model aims to model the trending of the physical quantity in a chosen spatial zone, for example an urban zone, comprising a set of physical obstacles and subject to different initial conditions; it does not target modelling the physical obstacles as such. The chosen spatial zone can be any, since the invention allows a model to be learned and the model is then applicable to any type of spatial zones.

The second level 24 of the physical quantity in a chosen spatial zone determined in the operation phase 200 can be rendered to a user via a graphical interface making it possible to visualize the level of the physical quantity in the chosen zone, represented in three dimensions. The visualization of this result allows a user to trigger corrective measures as a function of the level of the physical quantity, for example by comparing this level to a predefined alert threshold.

FIG. 3 represents a general outline schematic of the operation of a learning procedure for solving a PDE subject to spatial constraints according to an embodiment of the invention. The step 110 of determination of the model 13 for said physical quantity comprises a step 120 of determination of a simplified solution Ũ of the system of partial differential equations in the absence of physical obstacles. This step is performed by analytical or numerical methods, completely disregarding the spatial constraints.

In this step, the equation (1) subject to a subset of constraints of (2) and (3), not including the spatial constraints, is solved. Even if it means simplifying the equation (1), it is still possible to reach a PDE that is easy to solve analytically or numerically. This solution (denoted Ũ in its matrix form) serves to initialize the learning model. The initialization of Ũ makes it possible to reduce the complexity of the learning algorithm, facilitate the convergence thereof, and obtain a better prediction accuracy.

The step 110 comprises a step 130 of representation of the first set of physical obstacles 11 in the learning spatial zone, for example an urban zone, in the form of a first matrix of spatial constraints Mc1. The values of the matrix of spatial constraints can be adjusted by a neural model. This step aims to take account of the physical environment of the phenomenon being studied.

The step 110 comprises a step 140 of application, to the simplified solution Ũ, of a masking function 141 parameterized by the first matrix of spatial constraints Mc1 to obtain a first intermediate solution Ũ_{M} of the system of partial differential equations in the presence of the first set of physical obstacles 11. This step 140 consists in applying the spatial constraints to the simplified solution. As will be explained using examples, the masking step makes it possible to have the spatial constraints applied but lifts the physical constraints.

Next, the step 110 comprises a step 150 of application, to the first intermediate solution Ũ_{M}, of a correction function 151 determined by a neural network, to obtain the model for said physical quantity and a first corrected solution Ũ_{C} of the physical quantity in the learning zone. The application of the correction restores the physical constraints and establishes the space-time dynamics of the phenomenon (level of the physical quantity), but, on the other hand, lifts some spatial constraints. The step 150 consists in applying the post-masking result of a sequence of so-called correction nonlinear transformations learned by a neural network.

In order to re-establish the physical constraints, the step 110 also comprises a step 140 of application, to the first corrected solution Ũ_{C}, of the masking function 141 parameterized by the first matrix of spatial constraints Mc1 to obtain the model 13 of the physical quantity of the system of partial differential equations in the learning zone. The result is the model 13. These iterations also make it possible to determine a first level 14 of the physical quantity in the presence of the first set of physical obstacles 11.

As is represented in FIG. 3, it is possible to repeat the steps 150 and 140 several times. It is possible to determine a convergence threshold. The learning consists in updating the parameters of the neural network to minimize the cost function (for example the MSE, standing for Mean Squared Error). The convergence threshold is reached when, for example, the MSE (Mean Squared Error) value is at a minimum. The last step should be the step 140 of application, to the first corrected solution Ũ_{C}, of the masking function 141 to re-establish the spatial constraints. By alternating masking and correction, the model evolves progressively towards the final solution 13. The masking-correction combination makes it possible to introduce the effect of the spatial constraints without directly associating with them a weight in the learning model. Without that, the model would be very complex (large number of learning parameters) and consequently more inclined to overlearning (learning the data by heart rather than inferring the underlying dynamics). At the end of the learning phase, the model 13 makes it possible to approximate the solution of the PDE under different spatial constraints.

To do this, in the operation phase, the step 200 of determination of the second level 24 of the physical quantity in the predefined zone comprises the following steps:
representation (230) of the second set of physical obstacles 21 in a zone chosen by the user that is different from the learning zone in the form of a second matrix of spatial constraints Mc2. This step makes it possible to take account of the physical environment in which the level of the physical quantity of interest is wanted to be evaluated. It is therefore here a set of obstacles different from the first set of obstacles used in the learning phase.
application (240), to the model 13 (determined just once in the learning phase), of a masking function 242 parameterized by the second matrix of spatial constraints Mc2 to obtain a second intermediate solution Ũ_{M2} of the system of partial differential equations in the presence of the second set of physical obstacles 21;
application (250), to the second intermediate solution Ũ_{M2}, of the correction function 151 of the model, to obtain a second corrected solution Ũ_{C2} of the physical quantity in the zone which has been chosen for the second set of physical obstacles 21;
application (240), to the second corrected solution Ũ_{C2}, of the masking function 242 parameterized by the second matrix of spatial constraints Mc2 to obtain the second level 24 of the physical quantity of the system of partial differential equations in the chosen zone in the presence of the second set of physical obstacles 21.

FIG. 4 schematically represents an illustration of a constraint matrix according to an embodiment of the invention, used in the step 130 or 230 of representation of a set of physical obstacles in the chosen zone considered in the form of a matrix of spatial constraints. The matrix of spatial constraints, denoted M_{C1}, is defined as being a 2D representation of the environment, the centre of which corresponds to the source of the phenomenon being studied (for example the phenomenon being studied can be a concentration of a pollutant in the air and the source is then the place of emission of this pollutant). The absence of constraints is represented by the value 1. For each constraint of different nature (or composition), a value lying between 0 and 1 is associated with it. This choice can be based on the a priori knowledge of the expert or be random (provided that the same value is associated with the same type of constraint). In the first case, the values of the matrix M_{C1} depend on the type of physical interaction at the interface of the spatial constraints. In the example of FIG. 4, as an illustrative and nonlimiting example, the surface 1 is reflecting, it has the value 0 associated with it. The surfaces 2 and 3 are both absorbent, the first being more than the second. They are respectively assigned the values 0.3 and 0.7.

FIG. 5 represents a general outline schematic of the masking function 141 according to an embodiment of the invention. The masking function is a transformation of the simplified solution U (without taking account of the spatial constraints), parameterized by the matrix of spatial constraints M_{C}. The aim initially is to find an encoding for the values of M_{C} that makes it possible to adjust (if necessary) the effect of the different compositions of the spatial constraints on the phenomenon being modelled (the concentration of the pollutant in the example mentioned above). This is performed by a group of convolution operations with nonlinear activation function (of ReLU or Rectified Linear Unit type), involving k filters of [symbol] ^{a×a}. The latter are applied to the matrix of spatial constraints to which there will previously have been concatenated zeros at the outlines (zero-padding). The maps of characteristics produced are merged by a convolutional filter of 1×1 size. The latter serves to calculate a weighted sum of the maps of characteristics before applying a nonlinear operator. A matrix of dimensions similar to M_{C}, denoted C_{C}, is therefore obtained. The introduction of this additional degree of freedom allows for the masking to be adapted to the correction model during the learning (back-propagation). This is of benefit particularly if the edge effects are unknown or difficult to quantify. Moreover, the post-learning analysis of the matrix C_{C} can make it possible to quantitatively identify the effect of an obstacle of given composition on the phenomenon being studied.

Finally, the spatial constraints are applied to the simplified solution Ũ by an element-by-element multiplication to obtain the matrix Ũ_{M}:

Ũ_{M}=Ũ⊙C_{C}
⊙ being the Hadamard matrix product.

At this stage, the intermediate solution, denoted Ũ_{M}, is obtained.

The masking function 141 has the advantage of having the spatial constraints observed. It does however result in discontinuities and artefacts that are inconsistent with the physics of the phenomenon being studied. The space-time dynamic is also not yet considered.

To model the space-time dynamic and re-establish the constraints of physics, a sequence of nonlinear transformations, called correction function 151 and learned by a neural network, is applied to Ũ_{M}. It should be noted that, since the neural network does not know the geometry of the problem (it is not an input of the function), the result of the correction function tends to lift the observance of the spatial constraints.

The correction function can be approximated by different types of neural networks, in particular a convolutional network or a network of encoder/decoder type. The choice depends more generally on the PDE to be solved, but a good practice is to test the proposed learning procedure with these two types of neural networks.

Hereinbelow, the learning method for solving partial differential equations of physical phenomena subject to spatial constraints is described by means of two examples.

FIG. 6 represents a flow diagram detailing the steps of implementation of a learning procedure for solving fluid mechanics of PDEs according to a first exemplary embodiment of the invention. In this example, the phenomenon being studied is an accidental discharge of atmospheric pollutant in an urban environment and the physical quantity for which the trending is wanted to be tracked is the concentration of this pollutant in the chosen urban environment.

In the case of an accidental atmospheric discharge of a pollutant in an urban environment, it is vital to predict as rapidly as possible the zones that are at potential risk and implement population protection measures (containment, evacuation, etc.).

Generally, the flow of the air and the dispersion of the pollutant are simulated by numerically solving the Navier-Stokes equations and the pollutant transport equation. Since the early 2000s, the CFD (Computational Fluid Dynamics) models have been adapted to take account of the characteristics of the natural or built environment. These models make it possible to realistically reproduce the local flows and the space-time distribution of a pollutant, including on sites with complex relief and which have buildings. These models have been the subject of experimental validation campaigns which show that the numerical results are very close to the field reality. Hereinafter in this document, the results of physical models are therefore likened to the field reality. By contrast, the CFD models generally require a lot of computation time and significant resources (memory, processors, etc.).

By way of illustration, the concentration, integrated over two hours, of a pollutant hypothetically discharged accidentally right in the town centre of Grenoble was simulated for a very large number of meteorological conditions and of source locations. The results are presented in the form of 2D mappings at man height of the integrated concentration field. It is these results which are used in the learning and constitute the reference in the implementation of the algorithms presented. In other words, the learning data are composed of a 3D mapping or morphology of a real learning spatial zone and of a set of scenarios of different meteorological conditions and of different positions of a source of pollutant in that zone. The learning zone is, for example, an urban zone.

Advantageously, the chosen geographic zone is large enough to incorporate a wide variety of buildings and urban obstacles which are representative of an average urban zone, such that the model trained on this particular geographic zone will then be applicable to other spatial zones.

In the learning phase, a simplified solution without spatial constraints is determined first of all. In this case, no account is taken of the buildings, vehicles, etc. present in the urban environment.

U is, here, an analytical solution which provides the concentration of the pollutant according to the Gaussian plume formula and uses as parameters the direction θ and speed v of the wind above the urban canopy. In its formulation, this module considers the ground flat and disregards any building, which allows for a direct analytical resolution. Obviously, this solution is merely an approximation which is far from the field reality in an urban centre of a town with the possibly complex 3D morphology of the buildings.

The Gaussian solution is analytically determined as follows:

$$C ( x , y , z = {z}_{0} , t ) = \frac{Q}{2 {πσ}_{x} {σ}_{y}} exp ( - \frac{{( x - vt )}^{2}}{2 {{σ}_{x}}^{2}} ) exp ( - \frac{{y}^{2}}{2 {{σ}_{y}}^{2}} ) \qquad ( 4 )$$

in which:
C represents the concentration in the air at the point of coordinates (x, y, z) at the instant t
Q represents the quantity discharged
v represents the speed of the wind
t represents the time since the start of the discharge
z₀ represents the height of the source of the discharge
x, y, z are the relative coordinates of the point concerned with respect to the point of discharge (the x axis corresponds to the direction of the wind θ, the y axis is transversal to the direction of the wind)
σₓ and σ_{y} are the standard deviations of the Gaussian distribution (which can be experimental, or collected in a table for different meteorological conditions available to the public).

In the equation (4), the concentration is calculated at the same height as that of the discharge (z₀), hence the absence of dependency on z. With the equation (4), the simplified solution is available. The next step is to represent the matrix of spatial constraints.

FIG. 7 schematically represents an illustration of an urban zone comprising a set of physical obstacles (town centre of Grenoble) to be taken into account in a constraint matrix according to the first exemplary embodiment of the invention. The matrix of spatial constraints is represented by a 2D cross-section of the map of the buildings. The latter are assumed to be of similar composition (they all have an effect on the flow) and are considered, in this example case, as being impermeable to the pollutant. A binary matrix is therefore defined in which the elements are at 0 when a building is present and at 1 otherwise.

Next, for the masking function 141, a single convolution filter of size 3×3 is considered, in which the values are set at

$${K}_{1} = ( \begin{matrix}0 & 0 & 0 \\ 0 & 1 & 0 \\ 0 & 0 & 0\end{matrix} ) .$$

Since the effect of the buildings on the pollutant (impermeability) is perfectly modelled by the matrix of spatial constraints, a choice is made to set the values of the filter (non-trainable) such that C_{C}=M_{C}. Next, the integrated concentrations of the Gaussian plume Ũ are multiplied by C_{C}. The intermediate solution is then obtained, to which a correction function will be applied.

For that, a neural network of encoder/decoder type is used, composed of an input layer, three hidden layers and an output layer:
the input layer transforms the matrix Ũ_{M} into a vector of size 100×100;
the three hidden layers are each composed of 2048 neurons, with an ReLU activation function;
the output layer (decoder) is composed of 10⁴ neurons, to reconstruct a matrix of the same dimensions as Ũ_{M} (100×100).

Once the correction function is known, it is applied to the intermediate solution. Then, the masking function will be applied once again to re-establish the spatial constraints. The model is then obtained which can subsequently be used, in an operation phase, to provide the integrated concentration of the pollutant in any urban zones (Grenoble or elsewhere) until now never encountered during the learning phase.

FIG. 8 illustrates maps of concentrations (logarithmic scale) of the final result and of the intermediate results of the learning model (in operation phase) on the atmospheric dispersion of a pollutant in the town centre of Grenoble according to the first exemplary embodiment of the invention.

The solution of the Gaussian model (top left in FIG. 8) gives an idea of the dispersion in the absence of obstacles; on a flat terrain, the flow has a conical form in the direction of the wind. By applying a binary masking (top right in FIG. 8), the limitation of the flow of the Gaussian plume to the fluid zones (streets) can be noted on the medium. At this stage, the interaction with the buildings is not yet taken into account and abrupt and artificial discontinuities of the concentration levels can be noted. The correction function then makes it possible to smooth the distribution of the pollutant and reflect the effect of the street intersections around the source (bottom left in FIG. 8). Finally, the spatial constraints are re-established using the second masking function (bottom right in FIG. 8).

FIG. 9 represents the distribution of the pollutant simulated by a reference CFD model and likened to the field reality.

The table below compares the intermediate results and the final prediction with the field reality which is, it should be noted, the solution of the reference CFD model (represented in FIG. 9). Two metrics are considered: the mean squared error which measures the prediction error and the SSIM (abbreviation for Structural Similarity) which is generally used to quantify the similarity between images. Note that the final prediction is accurate, with an SSIM at 80% and a low mean squared error. Also, note the increase in the MSE (Mean Squared Error) after the correction step and, consequently, the importance of the two maskings in the overall process.

| | Gaussian | | | Final |
|---|---|---|---|---|
| Metric | solution | Masking | Correction | prediction |
| Mean | 2.1 | 1.7 | 2.3 | 0.6 |
| Squared | | | | |
| Error (MSE) | | | | |
| SSIM | 0.6 | 0.67 | 0.52 | 0.79 |

It can also be noted that the prediction generated is quasi-instantaneous (a few milliseconds on an ordinary laptop: 16 Gb RAM, Intel i5 CPU). The method of the invention thus makes it possible to accurately, and extremely rapidly, determine a level of a physical quantity (here, a concentration of a chemical species) in a plurality of nonfixed environments, with spatial constraints until now not encountered in the learning phase.

FIG. 10 represents a flow diagram detailing the steps of implementation of a learning procedure for solving acoustic wave propagation PDEs according to a second exemplary embodiment of the invention. In this example, the phenomenon being studied is the propagation of acoustic waves in the presence of obstacles and the physical quantity for which the trending is wanted to be tracked is the acoustic pressure level in the chosen physical environment.

Sound pollution has become a major issue that can have serious repercussions on health and on human quality of life. Phonic insulation planning for different noise sources (for example road lanes, work sites, factories, etc.) is therefore essential.

The propagation of soundwaves in an environment is modelled by a PDE derived from fluid mechanics, representing the trending of the acoustic pressure as a function of the coordinates of the space and time. In the presence of two-dimensional spatial constraints, the PDE is solved by numerical methods. In particular, T. Komatsuzaki et al. (see reference [5]) propose a modelling by cellular automata, based on a resolution method with finite differences on a rectangular meshing with local linearization of the PDE. The reflective nature of the spatial constraints is represented in the automata transition rules. The authors show that their modelling of acoustic propagation in the presence of obstacles is very realistic given a fine meshing, which leads to extremely lengthy computation times and requires significant computing resources. The results of this model will be considered hereinbelow as the field reality.

For this example, the propagation of acoustic waves was simulated for different configurations of spatial constraints generated randomly (numbers of obstacles, their geometrical forms and their positions). The sound source consists of a sinusoidal disturbance located at the centre of the propagation medium. The results are presented in the form of 2D mappings of the acoustic pressure level, which represent the intensity of the noise in steady state conditions at each point of the space. These results are used to feed and validate the learning procedure represented in FIG. 10.

In other words, in this second exemplary application of the invention, the learning data can be composed of several 3D mappings or morphologies of different real or simulated spatial zones and a set of scenarios of different positions of the sound sources in the spatial learning zones as well as different characteristics of the sound sources (type of source, notably type of the source emitting device).

The solution Ũ is derived from the cellular automata model presented previously. This involves simulating the propagation of an acoustic wave in a free medium, that is to say in the total absence of obstacles.

FIG. 11 schematically represents an illustration of physical obstacles to be taken into account in a constraint matrix according to the second exemplary embodiment of the invention. The constraint matrix represents, in a 2D cross-section, the physical obstacles in the propagation medium. The latter are assumed to be impermeable and reflect all of the acoustic wave. A binary matrix is therefore defined, the elements of which are at 0 in the presence of an obstacle and at 1 otherwise.

For the masking function, a single convolution filter of size 3×3 is considered, the values of which are set at

$${K}_{1} = ( \begin{matrix}0 \\ 0 \\ 0\end{matrix} \begin{matrix}0 \\ 1 \\ 0\end{matrix} \begin{matrix}0 \\ 0 \\ 0\end{matrix} ) .$$

The obstacles are media in which the acoustic wave is not propagated, which is perfectly modelled by the matrix of spatial constraints. A choice is made to set the values of the filter (non-trainable) such that C_{C}=M_{C}. Next, the acoustic pressure levels Ũ are multiplied by C_{C} and an intermediate solution Ũ_{M} is obtained.

FIG. 12 represents a general outline schematic of the correction function for the acoustic propagation modelled by a multi-scale convolutional network according to an embodiment of the invention.

In this example, an innovative multi-scale convolutional network is used. The input matrix Ũ_{M} is distributed in the same way to several convolution branches. Each branch i∈{0, 1, . . . , 9} is composed of 10 layers, each of which consists of one convolution with 100 kernels of dimensions 3+2i×3+2i followed by an Exponential Linear Unit (ELU) activation. The 100 maps of characteristics produced at each layer, of the same dimension as Ũ_{M}, are subsequently centred and reduced (Batch Normalization, abbreviated BN) before being transmitted to the next layer. On arrival at the last layer of the branch, the maps of characteristics are merged by a convolutional filter of size 1×1.

At this stage, each branch produces a matrix of the same dimension as Ũ_{M}. These matrices are then merged one last time to produce the output matrix.

It is important to note that this is a nonlimiting example of modelling of the correction function by a multi-scale convolutional network. The person skilled in the art can, based on his or her knowledge, choose other suitable types of neural networks.

To finish, the masking function is applied to the output matrix from the preceding step to correctly take account of the space-time reality. As mentioned previously, several masking and correction and masking iterations can take place.

The correction function can be determined in a learning phase comprising a step of execution of several iterations of a machine learning algorithm, receiving as input the intermediate solution, the machine learning algorithm being configured to determine the correction function. The iterations of the machine learning algorithm are stopped after the execution of a predetermined number of iterations or when the error between the level of the physical quantity in the predefined zone and a reference level of the physical quantity in the predefined zone is lower than a predetermined convergence threshold.

When the parameters of the correction function are learned and the model for the physical quantity is obtained (here, the model for the acoustic pressure level), the resulting model is used, in an operation phase, to predict the acoustic pressure level in an environment in which the form and the arrangement of the obstacles are unpublished (not encountered during the learning phase).

FIG. 13 illustrates maps of acoustic pressure levels (in decibels) of the final result and of the intermediate results of the learning model (in operation phase) on the acoustic propagation in an environment with obstacles according to the second exemplary embodiment of the invention. The numerical model solution (top left in FIG. 13) is valid in a free environment (without obstacles): the propagation is isotropic and the effect of constructive or destructive interferences, symmetrical with respect to the source at the centre of the map, can be noted. The application of a binary masking (top right in FIG. 13) forces the absence of propagation of the sound within the obstacles. Next (bottom left in FIG. 13), the correction function makes it possible to reproduce the physical behaviour derived from the interaction between the obstacles and the acoustic wave (reflection and interference). Finally, the spatial constraints at the interfaces of the obstacles are re-established using the second masking function (bottom right in FIG. 13).

FIG. 14 represents the acoustic pressure levels, simulated by the cellular automata model described in the reference [5] and likened to the field reality.

The table below compares the intermediate results and the final prediction with the field reality which is, it should be noted, the solution of the cellular automata model (FIG. 14). As for the example of atmospheric dispersion of the pollutant, two metrics are considered, which are the MSE and the SSIM. Once again, a significant improvement of the SSIM and a strong lowering of the MSE owing to the consecutive masking and correction operations is noted.

| | Numerical | | | Final |
|---|---|---|---|---|
| Metric | solution | Masking | Correction | prediction |
| Mean | 1104 | 53 | 114 | 22 |
| Squared | | | | |
| Error (MSE) | | | | |
| SSIM | 0.1 | 0.38 | 0.52 | 0.6 |

The prediction generated by the learnt model takes on average 1 minute of computation (without parallelization, on an ordinary laptop: 16 Gb RAM, Intel i5 CPU).

The method according to the invention can comprise a step of rendering of the results obtained in the operation phase via a graphical interface in the form of a 2D mapping of the targeted spatial zone in which is represented the estimated level of the physical quantity (chemical or sound pollutant in the case of the abovementioned two application examples).

The graphic visualization of the results can incorporate an alert threshold allowing the user to visualize the zones in which the level of the physical quantity exceeds this alert threshold. For example, that can be done by associating different colour levels for different levels of the physical quantity.

The method of the invention can comprise a step of determination of applicable protection measures if the level of the physical quantity reaches the previously defined alert threshold. In the case of an accidental discharge of a chemical pollutant, the determination of protection can be a corrective action (filtration or collection of the pollutant) or a protective action (containment or evacuation of the population within a certain perimeter). In the case of acoustic wave propagation, the protection determination can be a protective action through the installation of suitable phonic insulation.

Thus, a user can implement protection or correction measures based on the graphic visualization of the results and on the implementation of the alert threshold in the graphical interface.

The protection or correction measures can be preventive, by simulating hypothetical or reactive sources of pollution by taking account of the real sources of pollution.

FIG. 15 represents a theoretical diagram of a variant of the learning procedure for solving a PDE subject to spatial constraints according to another embodiment of the invention. In this variant, the outputs of the correction/masking intermediate sublayers may be used by the correction functions further away in the architecture. That makes it possible to exploit the history of the transformations made when necessary to refine the learning.

The invention is implemented as a computer program comprising instructions for its execution. The computer program can be stored on a processor-readable storage medium.

The reference to a computer program which, when it is executed, performs any of the functions described previously, is not limited to an application program running on a single host computer. On the contrary, the terms computer program and software are used here in a general sense to refer to any type of computing code (for example, application software, firmware, micro-code or any other form of computer instruction) which can be used to program one or more processors to implement aspects of the techniques described here. The computing means or resources can notably be distributed (“Cloud computing”), possibly according to peer-to-peer technologies. The software code can be run on any appropriate processor (for example, a microprocessor) or processor core or a set of processors, whether provided in a single computation device or distributed between several computation devices (for example as possibly accessible in the environment of the device). The executable code of each program allowing the programmable device to implement the processes according to the invention can be stored, for example, in the hard disk or in read-only memory. Generally, the program or programs will be able to be loaded into one of the storage means of the device before being executed. A central processing unit can control and direct the execution of the instructions or software code portions of the program or programs according to the invention, instructions which are stored in the hard disk or in the read-only memory or else in the other abovementioned storage elements.

The computer program can comprise a graphical interface for rendering the results of the method according to the invention to a user in the form of a mapping of a zone in which the user wants to evaluate the level of the physical quantity targeted.

The invention can be coupled to an alert system making it possible to trigger an alert when the level of the physical quantity exceeds a predefined threshold in certain spatial zones.

The principle of the invention described in FIG. 2 therefore operates according to two successive phases: a first, learning phase in which a model 13 for a physical quantity is determined by means of machine learning receiving as input a first set of physical obstacles 11 and a first set of initial conditions 12, and a second, operational phase in which the model 13 previously determined is used to determine a level of the physical quantity for a second set of physical obstacles (not yet encountered by the model in the learning phase) and possibly other initial conditions.

It will be apparent more generally to the person skilled in the art that various modifications can be made to the embodiments described above, in light of the teaching which has just been disclosed to him or her. In the following claims, the terms used should not be interpreted as limiting the claims to the embodiments explained in the present description, but should be interpreted to include therein all the equivalents that the claims aim to cover by virtue of their formulation and the provision of which is within the scope of the person skilled in the art based on his or her general knowledge.

### REFERENCES

[1] Raissi, M., “Deep hidden physics models: Deep learning of nonlinear partial differential equations”, The Journal of Machine Learning Research, 932-955, 2018.
[2] Wang, R., “Comparison of machine learning models for hazardous gas dispersion prediction in field cases” International journal of environmental research and public health, 2018.
[3] Yu, R., “Long-term forecasting using tensor-train rnns”, Arxiv, 2017.
[4] Z. Long, B. D., “Learning PDEs from data with a numeric symbolic hybrid deep network. Journal of Computational Physics”, PDE-Net 2.0, 2019.
[5] Komatsuzaki, Toshihiko, Yoshio Iwata, and Shin Morishita, “Modelling of incident sound wave propagation around sound barriers using cellular automata”, In International Conference on Cellular Automata, 385-394. Springer, 2012.

1. A method implemented by computer, for determining a level of a space-time trending physical quantity in the presence of physical obstacles in a chosen spatial zone, the trending of said physical quantity being governed by a system of partial differential equations, the method comprising the following steps:
in a learning phase, determination by means of machine learning receiving as input a first set of physical obstacles belonging to a first learning spatial zone and a first set of initial conditions, of a model for said physical quantity, and, optionally, of a first level of the physical quantity in the learning spatial zone;
in an operation phase, determination of a second level of the physical quantity in a second spatial zone chosen from the model for said physical quantity receiving as input a second set of physical obstacles, distinct from the first set of physical obstacles, and a second set of initial conditions,
i. display of the second level of the physical quantity determined in the chosen spatial zone by means of a graphical interface,
ii. determination of applicable protection measures if the second level of the physical quantity reaches a previously defined alert threshold.

2. The method for determining a level of a physical quantity according to claim 1, wherein the step of determination of the model for said physical quantity comprises the steps of:
determination of a simplified solution (Ũ) of the system of partial differential equations in the absence of physical obstacles;
representation of the first set of physical obstacles in the learning spatial zone in the form of a first matrix of spatial constraints (Mc1);
application, to the simplified solution (Ũ), of a masking function parameterized by the first matrix of spatial constraints (Mc1) to obtain a first intermediate solution (Ũ_{M}) of the system of partial differential equations in the presence of the first set of physical obstacles;
application, to the first intermediate solution (Ũ_{M}), of a correction function determined by a neural network, to obtain the model for said physical quantity and a first corrected solution (Ũ_{C}) of the physical quantity in the learning spatial zone;
application, to the first corrected solution (Ũ_{C}), of the masking function parameterized by the first matrix of spatial constraints (Mc1) to obtain the first level of the physical quantity of the system of partial differential equations in the learning spatial zone in the presence of the first set of physical obstacles.

3. The method for determining a level of a physical quantity according to claim 2, wherein the step of determination of the second level of the physical quantity in a chosen spatial zone comprises the following steps:
representation of the second set of physical obstacles in the chosen spatial zone in the form of a second matrix of spatial constraints (Mc2);
application, to the model, of a masking function parameterized by the second matrix of spatial constraints (Mc2) to obtain a second intermediate solution (Ũ_{M2}) of the system of partial differential equations in the presence of the second set of physical obstacles;
application, to the second intermediate solution (Ũ_{M2}), of the correction function of the model, to obtain a second corrected solution (Ũ_{C2}) of the physical quantity in the chosen spatial zone for the second set of physical obstacles;
application, to the second corrected solution (Ũ_{C1}), of the masking function parameterized by the second matrix of spatial constraints (Mc2) to obtain the second level of the physical quantity of the system of partial differential equations in the chosen spatial zone in the presence of the second set of physical obstacles.

4. The method for determining a level of a physical quantity according to claim 2, wherein the masking function is a group of convolution operations with nonlinear activation function.

5. The method for determining a level of a physical quantity according to claim 2, wherein the correction function is determined in a learning phase comprising a step of execution of several iterations of a machine learning algorithm, receiving as input the intermediate solution, the machine learning algorithm being configured to determine the correction function.

6. The method for determining a level of a physical quantity according to claim 5, wherein the iterations of the machine learning algorithm are stopped after the execution of a predetermined number of iterations or when the error between the level of the physical quantity in the learning spatial zone and a reference level of the physical quantity in the learning spatial zone is lower than a predetermined convergence threshold.

7. The method for determining a level of a physical quantity according to claim 1, wherein the physical quantity is a pollutant, preferentially chemical or sound.

8. The method for determining a level of a physical quantity according to claim 1, wherein the machine learning of the model performed in the learning phase is fed by learning data comprising a mapping or morphology of the real learning spatial zone, comprising said first set of physical obstacles.

9. The method for determining a level of a physical quantity according to claim 8, wherein the learning data further comprise different sets of initial conditions applied to the learning spatial zone comprising at least different sets of positions of the sources of emission of said physical quantity in the learning spatial zone.

10. The method for determining a level of a physical quantity according to claim 9, wherein the different sets of initial conditions comprise different models of meteorological conditions impacting the learning spatial zone.

11. A computer program comprising instructions for the execution of the method according to claim 1, when the program is run by a processor.

12. A processor-readable storage medium on which is stored a program comprising instructions for the execution of the method according to claim 1, when the program is run by a processor.
